(19) United States
(12) Patent Application Publication
(10) Pub. No.: US 2007/0230140 A1
(43) Pub. Date: Oct. 4, 2007

(54) Device including lock mechanism of housing

(75) Inventors: Masakazu Oshitani, Kawasaki (JP); Takuji Naitoh, Kawasaki (JP); Tomoaki Kazama, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/643,790

(22) Filed: Dec. 22, 2006

(30) Foreign Application Priority Data
Mar. 28, 2006 (JP) JP2006-088272

(51) Int. Cl. H05K 7/16

(52) U.S. Cl. 361/726

(57) ABSTRACT

To provide a technology of controlling a lock mechanism of a housing in accordance with a predetermined condition. An information processing device has a housing of which at least part is openable, a lock unit locking the housing not to open, and a lock control module controlling the lock unit in accordance with a predetermined condition and making the lock unit perform locking or unlocking. The information processing device further has further an instruction receiving module receiving an instruction from a user, wherein the lock control module may make the lock unit perform locking or unlocking, corresponding to the instruction and the state of the power source as the predetermined conditions.

### BACKGROUND OF THE INVENTION

The present invention relates to a technology of controlling a lock mechanism of a housing of an information processing device (computer) etc.

Over the recent years, the information processing devices such as personal computers have rapidly spread, wherein a great majority of people have daily utilized the information processing devices. Therefore, users have an increased number of occasions of maintaining the information processing devices. Particularly, the personal computer has occasions of updating software and peripheral devices, which might involve changing a hardware configuration of the personal computer. For example, operations such as adding a memory, inserting an extension board and exchanging a hard disc are conducted in a way that opens the housing of this personal computer.

An interior of the housing of the personal computer has a fan rotating at a high speed and components to which a high voltage is applied during a supply of electricity, and its is therefore required that the attention be paid so as to invariably stop the supply of the electric power given from a power source before opening the housing.

Further, a technology disclosed the following Patent document 1 and 2 are given as the prior art related to the invention of the present application.

[Patent document 1] Japanese Patent Application Laid-Open Publication No. 2004-341947

[Patent document 2] Japanese Utility Model Registration Publication No. 3072398

### SUMMARY OF THE INVENTION

All the users are not, however, necessarily familiar with handling the information processing devices, and hence a device, which can be used without paying special attention, is desired.

Moreover, because of the configuration that the housing is easily opened for the maintenance, such a problem exists that the expensive components within the housing and a storage medium stored with important information are easy to be stolen.

Such being the case, the present invention provides a technology of controlling a lock mechanism of the housing in accordance with a predetermined condition.

The present invention adopts the following configurations in order to solve the problems.

Namely, a device of the present invention comprises a housing of which at least part is openable, a lock unit locking the housing not to open, and a lock control module controlling the lock unit in accordance with a predetermined condition and making the lock unit perform locking or unlocking.

The predetermined condition may be a condition corresponding to a state of a power source. For instance, the lock control module may make the lock unit perform locking if the power source is in an electric power supply state and may make the lock unit perform unlocking if the power source is in an electric power non-supply state. With this contrivance, the housing does not open during the supply of the electricity, and therefore it does not happen that a user mistakenly conducts the maintenance during rotations of the fan and during application of a voltage.

The device may further comprise an instruction receiving module receiving an instruction from a user, wherein the lock control module may make the lock unit perform locking or unlocking, corresponding to the instruction and the state of the power source as the predetermined conditions. This contrivance enables the lock unit to be controlled according to the conditions set by the user such as locking only during the supply of the electric power, locking all the time and unlocking all the time.

The device may have an operating portion that is operated by a supply of the electric power from the power source and is provided within the housing. For instance, the operating portion may be a rotary portion rotated by the supply of the electric power. With this configuration, it is possible to prevent damage to the operating portion due to the maintenance mistakenly conducted during the operation of the operating portion (rotary portion).

The lock unit and/or the lock control module may be operated by the supply of the electric power from the power source. With this operation, the lock unit and/or the lock control module are or is operated, i.e., the locking or the unlocking is carried out inevitably during the supply of the electric power from the power source, and hence a mechanism for detecting a state of the supply of the electric power can be omitted.

Further, a lock control method of the present invention is a method by which a device comprising a housing of which at least part is openable and a lock unit locking the housing not to open executes a step of referring to a predetermined condition, and a step of controlling the lock unit in accordance with the predetermined condition and making the lock unit perform locking or unlocking.

In the lock control method, the predetermined condition may be a condition corresponding to a state of a power source.

In the lock control method, the lock unit may be made to perform locking if the power source is in an electric power supply state.

The lock control method may further comprise a step of receiving an instruction from a user, wherein on the occasion of controlling the lock unit, the lock unit may be made to perform locking or unlocking, corresponding to the instruction and the state of the power source as the predetermined conditions.

In the lock control method, the device may include an operating portion that is operated by a supply of the electric power from the power source and is provided within the housing. Moreover, the operating portion may be a rotary portion rotated by the supply of the electric power.

In the lock control method, the lock unit and/or the control of the lock unit may be operated by the supply of the electric power from the power source.

Further, the present invention may be a lock control program that makes a computer execute the lock control method. Still further, the present invention may also be a readable-by-computer recording medium recorded with this lock control program. The computer is made to read and execute the program on this recording medium, whereby a function thereof can be provided.

Herein, the recording medium readable by the computer, etc. connotes a recording medium capable of storing information such as data, programs, etc electrically, magnetically, optically, mechanically or by chemical action, which can be read from the computer and so on. Among these recording mediums, for example, a flexible disc, a magneto-optic disc, a CD-ROM, a CD-R/W, a DVD, a DAT, an 8 mm tape, a memory card, etc are given as those demountable from the computer.

Further, a hard disc, a ROM (Read-Only Memory), etc are given as the recording mediums fixed within the computer.

According to the present invention, it is feasible to provide the technology of controlling the lock mechanism of the housing in accordance with the predetermined condition.

### BRIEF DESCRIPTION OF THE DRAWINGS

FIG. 1 is a schematic view of a configuration of an information processing device according to the present invention.

FIG. 2 is a view showing a state where a housing is closed.

FIG. 3 is a view showing a state where the housing is opened.

FIG. 4 is a view of an undersurface of a cover.

FIG. 5 is an explanatory view of a lock mechanism.

FIG. 6 is a chart showing lock conditions.

FIG. 7 is a flowchart of lock control when started up.

FIG. 8 is a flowchart of the lock control when cutting off a power source.

FIG. 9 is an explanatory view of the lock mechanism.

FIG. 10 is a flowchart of the lock control when started up in a first modified example.

FIG. 11 is a flowchart of the lock control when cutting off the power start in the first modified example.

FIG. 12 is a chart showing the lock conditions in a second modified example.

FIG. 13 is a flowchart of the lock control when cutting off the power start in the second modified example.

### DETAILED DESCRIPTION OF THE PREFERRED EMBODIMENT

One embodiment of the present invention will hereinafter be described with reference to the accompanying drawings. A configuration in the following embodiment is an exemplification, and the present invention is not limited to the configuration in the embodiment.

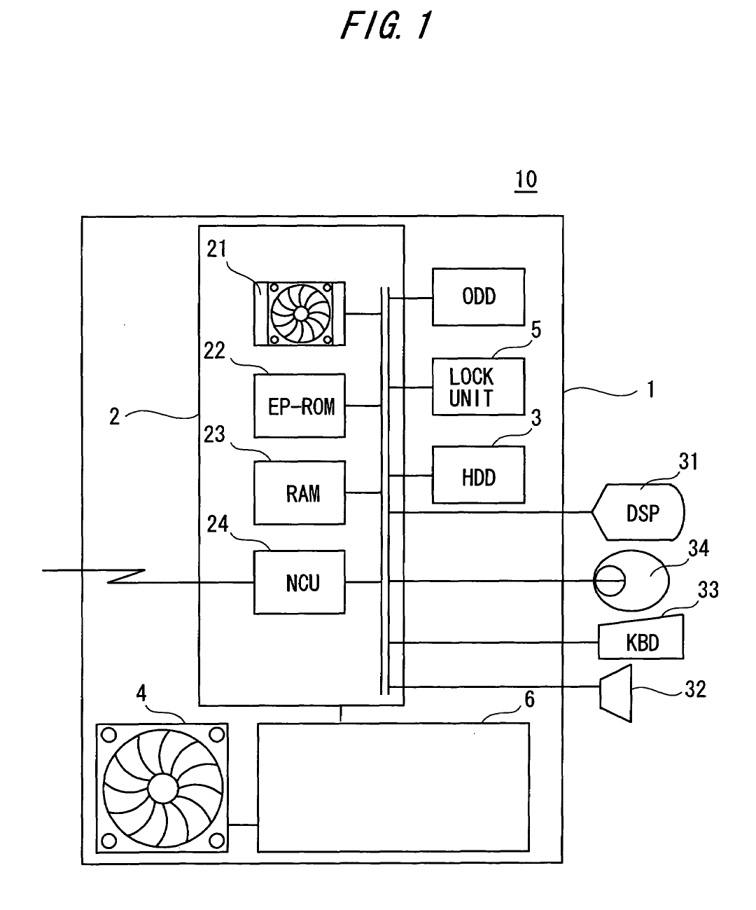

FIG. 1 is a schematic view of a configuration of an information processing device including a lock mechanism of a housing according to the present invention. As depicted in FIG. 1, an information processing device 10 in the present embodiment is, e.g., a personal computer having a housing 1 that incorporates a motherboard 2, a hard disc drive (HDD, a storage device) 3, a cooling fan (a rotating unit) 4, a lock unit 5 and a power source 6. The mother board 2 is provide with a central processing unit (CPU) 21, an EP-ROM (Erasable Programmable ROM) 22, a main memory (RAM) 23 and a communication control unit (CCU) 24. The cooling fan 4 starts rotating upon power-on of the power source 6 and keeps rotating all the time during a supply of the electricity, i.e., during an operation of the information processing device 10. The rotations of the cooling fan 4 discharge the air heated up within the housing 1 into an exterior of the housing 1, thereby restraining a rise in temperature within the housing 1.

Provided outside the housing 1 are a display (DSP) 31, a speaker 32, a keyboard (KBD) 33 and a mouse 34, which are connected to the motherboard 2.

The CPU 21 carries out a variety of processes by executing BIOS (Basic Input/Output System) stored in the EP-ROM 22, and an OS (Operating System; a basic software program), an application program and firmware that are stored in the HDD 3.

In the present embodiment, the CPU 21 functions also as an instruction receiving module and a lock control module by executing firmware (a lock control program).

This instruction receiving module receives a user's instruction via the keyboard 33, the mouse 34 and the communication control unit 24 and, if the instruction is a predetermined condition (which is, for the convenience's sake, referred to also as a lock condition) for controlling the lock unit 5, stores the EP-ROM 22 with this condition.

Moreover, the lock control module controls the lock unit 5 in accordance with the lock condition, thereby locking or unlocking the housing 1.

Then, the CPU 21 is provided with a heat sink and a cooling fan (a CPU cooler), whereby the cooling fan rotates during the supply of the electricity, i.e., during the operation of the information processing device 10 and thus cools off the CPU 21.

Note that the cooling fan 4 and rotary vanes of the CPU cooler are exposed within the housing 1 and therefore, if the housing 1 is opened during the operation, this might cause damages to fan and the rotary vanes because of wiring etc being caught in the fan and the rotary vanes.

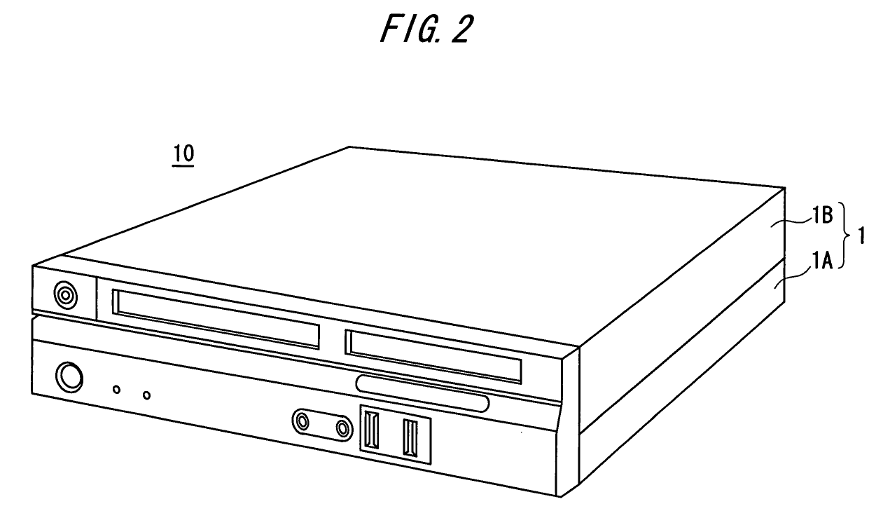

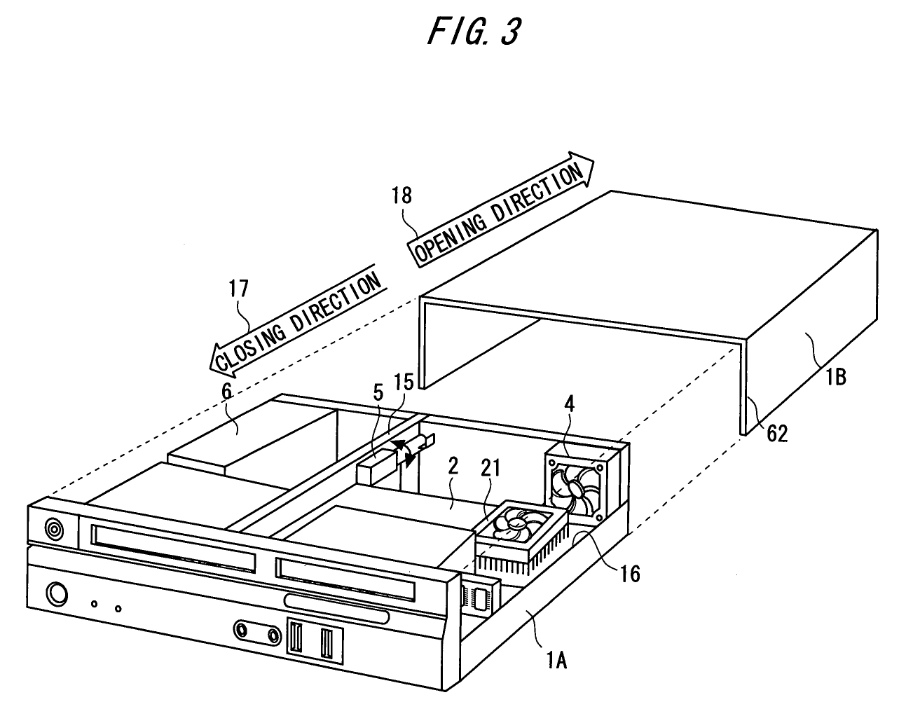

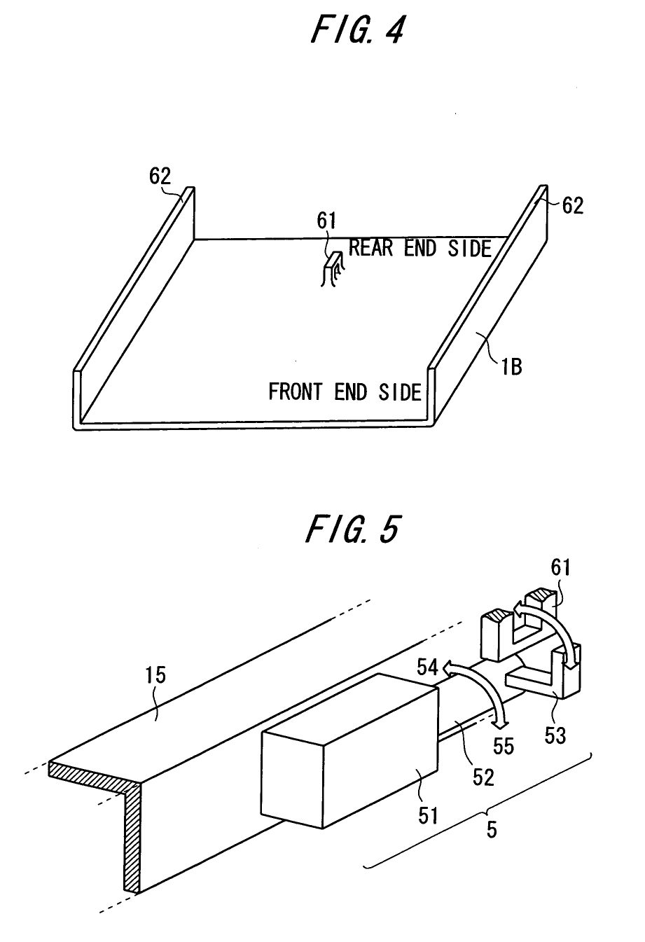

Next, the lock mechanism in the present embodiment will be explained with reference to FIGS. 2 through 7. FIG. 2 is a view depicting a state where the housing 1 is closed, FIG. 3 is a view showing a state where the housing 1 is opened, FIG. 4 shows an undersurface portion of a cover, and FIG. 5 is a view showing the lock mechanism.

The housing 1 is constructed of a base body 1A fitted with the motherboard 2 and the power source 6, while a cover 1B taking substantially a C-like shape in section becomes, as illustrated in FIG. 3, openable by moving the cover 1B in an opening direction 18 with respect to the base body 1A.

The lock unit 5 is, as depicted in FIG. 3, provided at an upper portion of a frame 15 provided fixedly to the base body 1A and is fixed to the base body 1A. The lock unit 5 in the present embodiment is a rotary type solenoid, wherein a rotary shaft 52 is movable with respect to a main body 51 fixed to the frame 15. Then, an L-shaped hook 53 is provided at a front end portion (which is the end portion on the side opposite to the main body 51 of the rotary shaft 52.

Further, an engagement loop member 61 engaging with the lock unit 5 is, as shown in FIG. 4, provided fixedly to a rear end portion of the undersurface (internal surface) of the cover 1B. Flanges 62 of this cover 1B are moved in a closing direction 17 along rails 16 of the base body 1A shown in FIG. 3, resulting in a state where the housing 1 is closed (FIG. 2), at which time the engagement loop member 61 of the cover 1B is, as illustrated in FIG. 5, positioned within a radius of rotation of the L-shaped hook 53. The L-shaped hook 53, when rotating in a locking direction 54 from this position, engages with the engagement loop member 61, thereby hindering the cover 1B from moving in the opening direction 18. Moreover, the L-shaped hook 53 rotates from this engaged state in a disengaging (unlocking) direction 55, resulting in a disengaged state (an unlocked state) of being disengaged from the engagement loop member 61, at which time the cover 1B gets movable in the opening direction 18. In the present embodiment, the lock unit 5 and the engagement loop member 61 configure the lock mechanism and are controlled in the locked state or the unlocked state by the lock control module.

Next, a lock control method executed by the lock control module according to the lock control program in the present embodiment, will be explained.

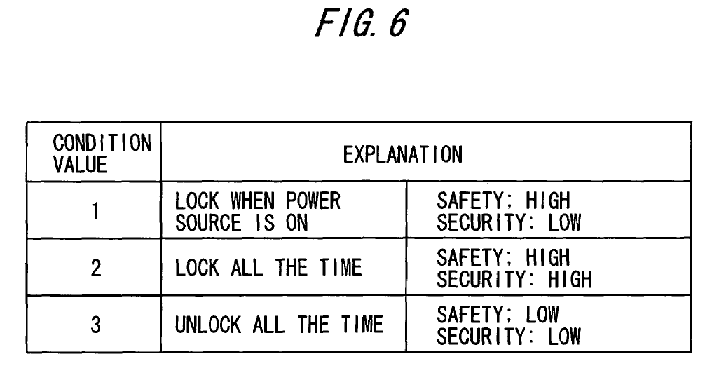

Note that a user previously inputs lock conditions (predetermined conditions) to the information processing device 10. For instance, in the present embodiment, as shown in FIG. 6, the user selects and inputs any one of a condition 1 [lock when the power source is ON], a condition 2 [lock all the time] and a condition 3 [unlock at all time].

The instruction receiving module of the information processing device 10 receiving this input stores the lock condition in the hard disc drive 3 or the EP-ROM 22.

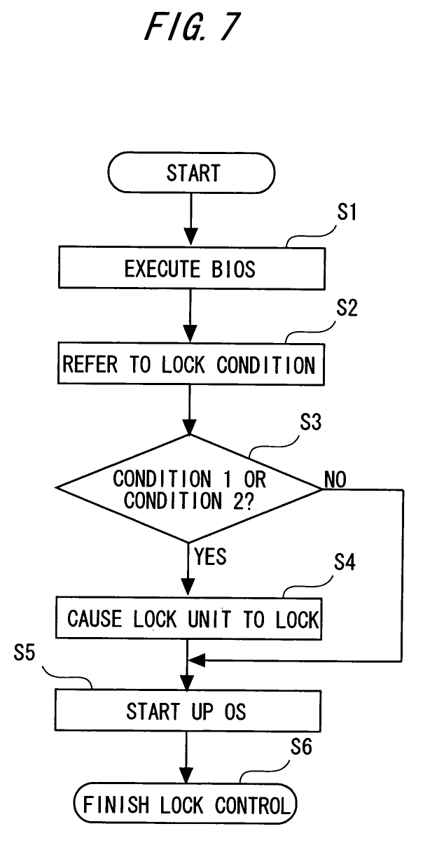

The information processing device 10, upon the power-on instruction given by operating a power source button, as shown in FIG. 7, starts up a POST (Power-On Self Test) program stored in the EP-ROM 22 and, after checking a variety of hardware components of the information processing device 10, executes the BIOS (step 1, which will hereinafter be abbreviated such as S1). In the present embodiment, when executing the BIOS, the firmware (the lock control program) is also executed, thereby starting the control of the lock mechanism.

The lock control module refers to the lock condition stored in the EP-ROM 22 (S2) and makes selection, based on the condition, as to whether the locking is conducted or not (S3).

If the lock condition set in the EP-ROM 22 is the condition 1 or the condition 2, the lock control module supplies the lock unit 5 with the electric power from the power source 6, and rotates the rotary shaft 52 in the locking direction 54, thereby locking the housing 1 (S4).

Then, the information processing device 10, upon starting up the OS, comes to an operating status (S5), and finishes the lock control when starting up (S6).

Through this operation, if the conditions 1 and 2 are set, the housing 1 is locked when power-on of the power source, and hence it does not happen that the user mistakenly opens the housing 1 during the supply of the electricity. Further, if the condition 2 is set, the housing 1 is locked all the time, and it is therefore possible to prevent the components such as the hard disc drive from being stolen.

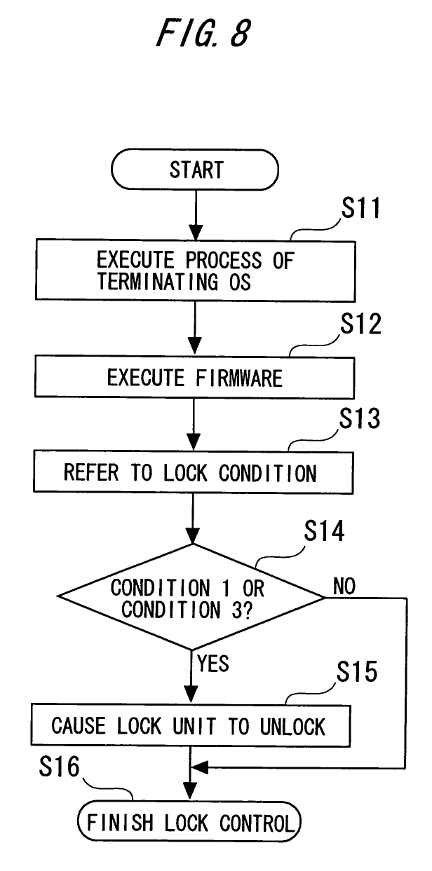

Moreover, the lock control method conducted when at shut-down (cut-off of the power source) of the information processing device 10 will be described with reference to FIG. 8.

Upon receiving a shut-down instruction from the user, the information processing device 10 carries out a process of terminating the OS (S11), and executes the firmware (the lock control program), thereby starting the lock control (S12).

To begin with, the lock control module refers to the EP-ROM 22 (S13) and makes, based on the lock condition, the selection as to whether to unlock (S14).

If the lock condition set in the EP-ROM 22 is the condition 1 or the condition 3, the lock control module supplies the lock unit 5 with the electric power from the power source 6 and rotates the rotary shaft 52 in the unlocking direction 55, thereby unlocking the housing 1 (S15).

Then, the information processing device 10 finishes the lock control conducted when at the shut-down, and switches OFF the power source (S16).

With this operation, the housing 1 is unlocked, thereby enabling the housing 1 to open for maintenance and so on.

It is to be noted that the input of the lock condition is not limited to the direct input to the information processing device 10 via the keyboard 33 and the mouse 34, and the lock condition may also be inputted to the information processing device 10 by mail and by remote operation from the communication control unit (CCU) 24 via a network. For instance, a system administrator (user) may input the lock condition to the plurality of information processing devices 10 via the network.

As described above, according to the present embodiment, the lock mechanism of the housing can be controlled corresponding to the predetermined condition. Accordingly, the user is able to perform the maintenance of the information processing device without paying special attention to the state of the power source and to the rotary unit.

Further, the housing, even if configured to be easily opened, can be locked on the occasions other than the maintenance, whereby the expensive components and the storage medium stored with important information can be prevented from being stolen.

### FIRST MODIFIED EXAMPLE

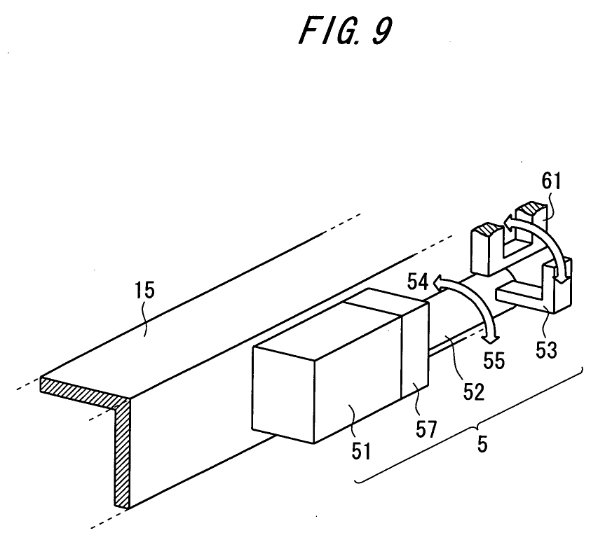

FIG. 9 shows an example in which the lock unit 5 is provided with a detection unit for detecting whether in the locked state or in the unlocked state. Note that other configurations are the same as those in the embodiment discussed above.

A detection unit 57, which is an absolute type encoder, detects whether or not the L-shaped hook 53 exists in a position engaging with the engagement loop member 61, i.e., detects whether the lock unit 5 is in the locked state or in the unlocked state.

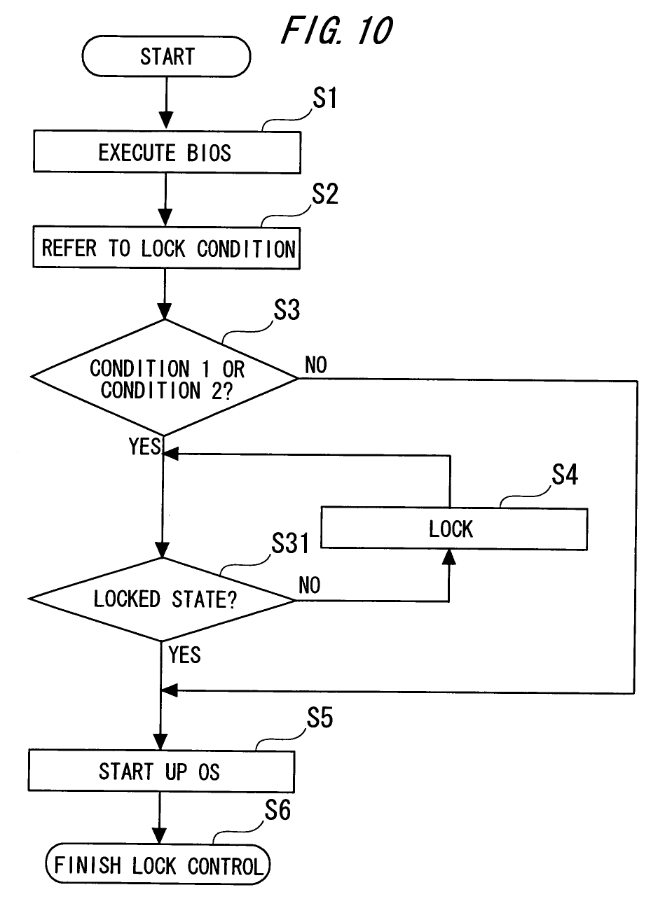

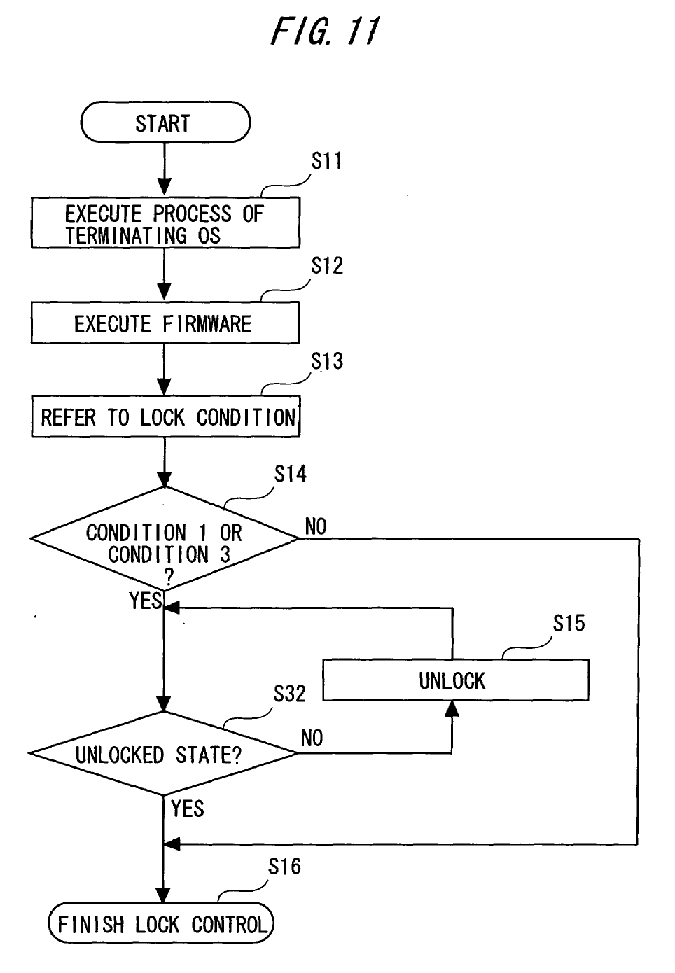

Then, as illustrated in FIG. 10, if the condition set in the EP-ROM 22 when started up is the condition 1 or the condition 2, the lock control module, when the detection unit 57 detects whether in the locked state or not (S31), controls the lock unit 5 on the basis of a result of this detection. Namely, the lock control module, if the result of the detection by the detection unit 57 is not the locked state, till reaching the locked state, supplies the lock unit 5 with the electric power from the power source 6 and rotates the rotary shaft 52 in the locking direction 54, thereby locking the housing 1 (S4).

Further, as shown in FIG. 11, if the condition set in the EP-ROM 22 when at shut-down is the condition 1 or the condition 3, the lock control module, when the detection unit 57 detects whether in the locked state or not (S32), controls the lock unit 5 on the basis of a result of this detection. Namely, the lock control module, if the result of the detection by the detection unit 57 is not the locked state, till the result of the detection by the detection unit 57 reaches the unlocked state, supplies the lock unit 5 with the electric power from the power source 6 and rotates the rotary shaft 52 in the unlocking direction 54, thereby unlocking the housing 1 (S15).

Through this operation, it is possible to control the lock unit 5 surely in the locked state or the unlocked state by detecting the state of the lock unit 5.

### SECOND MODIFIED EXAMPLE

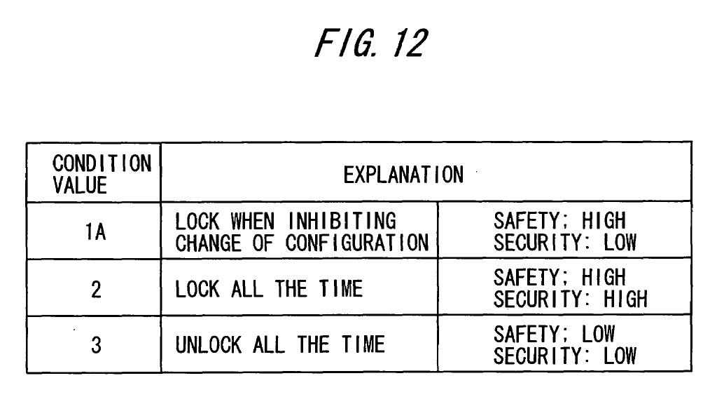

FIG. 12 is a chart showing an example another set of lock conditions. Note that other configurations are the same as those in the embodiment discussed above.

The information processing device 10 in a second modified example, if the user selects a pause status (hibernation), cuts off the power source after storing the hard disc drive 3 with the data on the memory. This operation enables storage of an operating status just before cutting off the power source of the information processing device 10, and enables the operation to resume from the status just before cutting off the power source when performing the power-on next time. When thus storing the operating status, however, if the hardware configuration is changed by exchanging the hard disc drive 3 and other peripheral devices, a contradiction occurs in contents of the storage.

Moreover, the information processing device 10 can back up the data and can make a reservation so that a task such as recording a TV program is carried out at predetermined time. When reserving this task, if the hardware configuration is changed by exchanging the hard disc drive 3 and other peripheral devices, inconvenience might occur.

Such being the case, the instruction receiving module in the second modified example, when receiving an instruction for a predetermined process, stores the EP-ROM 22 with information (an inhibition flag in the second modified example) showing inhibition of changing the configuration. Further, the instruction receiving module, in the case of finishing the predetermined process such as the information processing device 10 being reset from the pause status (hibernation) and all the reserved tasks being finished, deletes the inhibition flag from the EP-ROM 22.

On the other hand, as shown in FIG. 12, the user selects and inputs, as the lock condition, any one of a condition 1A [lock when inhibiting change of configuration], a condition 2 [lock all the time], and a condition 3 [unlock all the time].

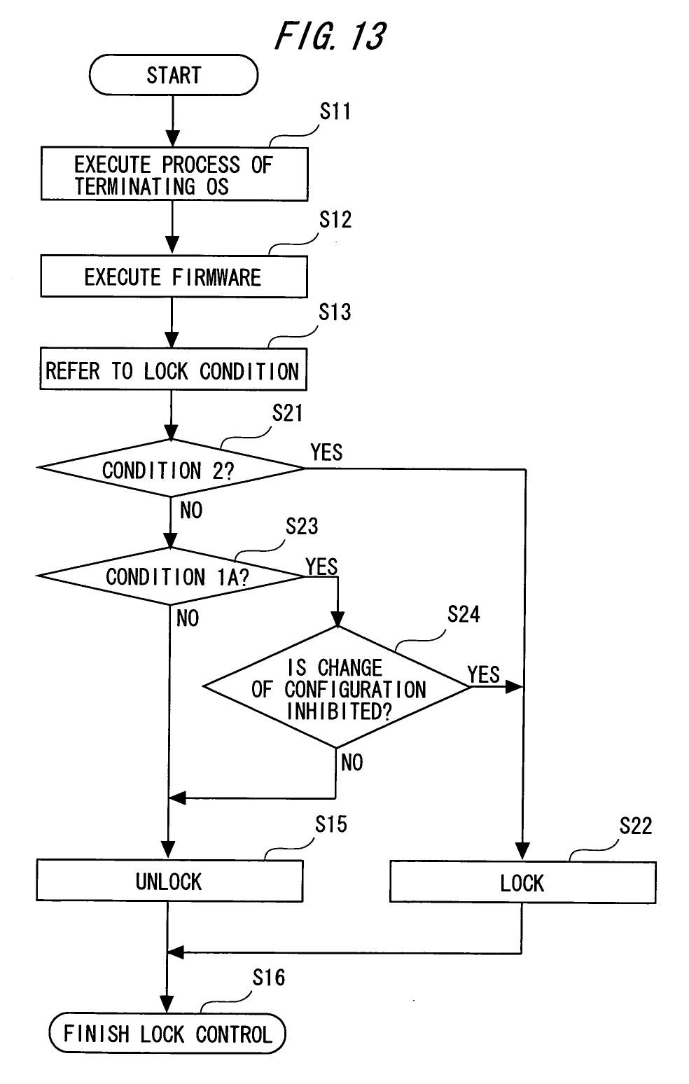

Then, as shown in FIG. 13, the lock control module refers to the lock condition set in the EP-ROM 22 when at the shut-down (S21), and, if being the condition 2, makes the lock unit 5 perform the locking (S22).

Moreover, if the condition set in the EP-ROM 22 is the condition 1A (S23), the lock control module refers to the EP-ROM 22 and judges whether the inhibition flag is set or not (S24). If this inhibition flag is set, the lock control module causes the lock unit 5 to do locking (S22).

Further, if the lock condition set in the EP-ROM 22 is the condition 3 or if the inhibition flag is not set in the EP-ROM 22, the lock control module makes the lock unit 5 perform unlocking (S15).

Thus, according to the second modified example, the lock mechanism of the housing can be controlled corresponding to whether the change of the configuration is inhibited or not. Accordingly, even if the user pays the attention to neither the pause status nor the reservation state of the task, such a possibility is eliminated that the hardware configuration is mistakenly changed.

Moreover, the lock control may also be conducted in a way that combines the conditions based on the state of the power source in the first modified example with the conditions based on the inhibition of the change of the configuration in the second modified example.

### Others

The present invention is not limited to only the illustrated examples given above and can be, as a matter of course, changed in a variety of forms in the range that does not deviate from the gist of the present invention.

### Incorporation by Reference

The disclosures of Japanese patent application No. JP2006-088272 filed on Mar. 28, 2006 including the specification, drawings and abstract are incorporated herein by reference.

What is claimed is:

1. A device comprising:
a housing of which at least part is openable;
a lock unit locking the housing not to open; and
a lock control module controlling the lock unit in accordance with a predetermined condition and making the lock unit perform locking or unlocking.

2. A device according to claim 1, wherein the predetermined condition is a condition corresponding to a state of a power source.

3. A device according to claim 2, wherein the lock control module makes the lock unit perform locking if the power source is in an electric power supply state and makes the lock unit perform unlocking if the power source is in an electric power non-supply state.

4. A device according to claim 2, further comprising an instruction receiving module receiving an instruction from a user,
wherein the lock control module makes the lock unit perform locking or unlocking, corresponding to the instruction and the state of the power source as the predetermined conditions.

5. A device according to claim 2, wherein an operating portion operated by a supply of the electric power from the power source is provided within the housing.

6. A device according to claim 5, wherein the operating portion is a rotary portion rotated by the supply of the electric power.

7. A device according to claim 2, wherein the lock unit and/or the lock control module are or is operated by the supply of the electric power from the power source.

8. A lock control method by which a device comprising a housing of which at least part is openable and a lock unit locking the housing not to open executes steps of:
referring to a predetermined condition; and
controlling the lock unit in accordance with the predetermined condition and making the lock unit perform locking or unlocking.

9. A lock control method according to claim 8, wherein the predetermined condition is a condition corresponding to a state of a power source of the device.

10. A lock control method according to claim 9, wherein the lock unit is made to perform locking if the power source is in an electric power supply state, and the lock unit is made to perform unlocking if the power source is in an electric power non-supply state.

11. A lock control method according to claim 10, further comprising a step of receiving an instruction from a user,
wherein on the occasion of controlling the lock unit, the lock unit is made to perform locking or unlocking, corresponding to the instruction and the state of the power source as the predetermined conditions.

12. A lock control method according to claim 9, wherein the device includes an operating portion that is operated by a supply of-the electric power from the power source and is provided within the housing.

13. A lock control method according to claim 12, wherein the operating portion is a rotary portion rotated by the supply of the electric power.

14. A lock control method according to claim 9, wherein the lock unit and/or the control of the lock unit are or is operated by the supply of the electric power from the power source.

15. A recording medium recorded with a lock control program making a device, comprising a housing of which at least part is openable and a lock unit locking the housing not to open, execute steps of:
referring to a predetermined condition; and
controlling the lock unit in accordance with the predetermined condition and making the lock unit perform locking or unlocking.

16. A recording medium according to claim 15, wherein the predetermined condition is a condition corresponding to a state of a power source.

17. A recording medium according to claim 16, wherein the lock unit is made to perform locking if the power source is in an electric power supply state, and the lock unit is made to perform unlocking if the power source is in an electric power non-supply state.

18. A recording medium according to claim 16 or 17, further comprising a step of receiving an instruction from a user,
wherein on the occasion of controlling the lock unit, the lock unit is made to perform locking or unlocking, corresponding to the instruction and the state of the power source as the predetermined conditions.

19. A recording medium according to claim 16, wherein the device includes an operating portion that is operated by a supply of the electric power from the power source and is provided within the housing.

20. A recording medium according to claim 19, wherein the operating portion is a rotary portion rotated by the supply of the electric power.

21. A recording medium according to claim 16, wherein the lock unit and/or the control of the lock unit are or is operated by the supply of the electric power from the power source.
